(19) United States
(12) Patent Application Publication
(10) Pub. No.: US 2006/0138599 A1
(43) Pub. Date: Jun. 29, 2006

(54) Semiconductor members having a halogenated polymeric coating and methods for their formation

(75) Inventor: Jesse Burl Thompson, Brentwood, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/025,439

(22) Filed: Dec. 29, 2004

(51) Int. Cl. H01L 23/58

(52) U.S. Cl. 257/629

(57) ABSTRACT

A coated semiconductor member is provided having a carbon-containing halogenated polymeric coating bonded to a surface thereof. The semiconductor member may take any of a number of forms, such as the form of a chip or a wafer containing one or more microelectronic devices. The coating may be bonded to the surface in a manner and quantity effective to provide the member an increased strength. In addition or in the alternative, the coating may improve the electrical performance of the member. Optionally, the coating has a microstructure associated with vapor phase in situ addition polymerization. Also provided is a method for coating a semiconductor member.

### BACKGROUND OF THE INVENTION

The present invention relates generally to coated semiconductor members. In particular, the invention relates to semiconductor members having a surface onto which a halogenated polymeric coating is bonded. Also provided are methods for coating semiconductor members.

Halogenated polymeric coatings have been employed in a number of different contexts. In particular, chlorinated and/or fluorinated polymers have received widespread attention for their chemical resistance, thermal stability, hydrophobicity, low coefficient of friction, etc. For example, chlorinated and/or fluorinated polymers such as ethylene-chlorotrifluoroethylene and ethylene-tetrafluoroethylene copolymers have been used to coat metal corrosive fume exhaust ducts. See, e.g., W. Douglas Obal, “Teflon Finishes in the Semiconductor Industry,” Cleanroom Technology, July 1999. In addition, perfluorinated polymers are well known for applications such as waterproofing textile products. See, e.g., John Soares, “Water-Proof Anything,” Technology Review, November 2003, pp 65-67. Recently, halogenated polymers such as polytetrafluoroethylene, polyvinylchloride, and polyvinylidene fluoride have been employed on silicon-based microfluidic devices. See, e.g., U.S. Pat. No. 6,752,966 to Chazan. In addition, halogenated polymers have been used in photoresist compositions. See, e.g., U.S. Pat. No. 6,797,739 to Kim et al.

Halogenated polymeric coatings may be formed from polyceramic materials. Generally, the term “polyceramic” refers to composite materials containing both polymeric and ceramic components. For example, polyacrylic acid may be reacted with silicate glass to form a polyceramic material. In some cases, polymerization may take place on the site of application. In dental applications, for example, radiation initiated polymerization techniques may be used to form polyceramic materials in situ. See, e.g., U.S. Pat. No. 6,652,281 to Eckhardt et al. Alternatively, polyceramic coatings may be formed by spraying or otherwise applying a layer of precursor liquid containing a solvent, and subjecting the liquid to conditions effective to form the coating. For example, precursor liquids containing chlorobenzotrifluoride from NIC Industries Inc. (White City, Oreg.) may be applied to a surface of an item to form a polyceramic coating on the surface. While polyceramic coatings have been applied to various items such as automotive parts and firearms, polyceramics coatings are generally unknown in the semiconductor microelectronic device industry.

In contrast, chlorinated and/or fluorinated polymeric coatings are known in the field of semiconductor-based microelectronic devices. For example, U.S. Pat. No. 6,284,563 to Fjelstad describes a method of making a microelectronic assembly by using a compliant layer that optionally includes a fluoropolymer. In addition, amorphous fluoropolymer materials sold under the trademark Teflon® from E.I. DuPont de Nemours and Company (Wilmington, Del.) have been used in optical, semiconductor processing and electronic applications. Additional chlorinated and/or fluorinated polymeric coatings are described in U.S. Pat. Nos. 4,966,813, 5,059,451, 6,391,472, 6,495,305, 6,680,160, and in U.S. Patent Application Publication Nos. 20010056144, 20020016057, 20020045125, 20020183426, 20030148601, 20040034134, 20040047108, and 20040067441.

Interlevel dielectrics used in integrated circuit manufacturing are generally ceramic materials having dielectric constants of about 4.0 to about 4.5. However, such interconnects associated with such dielectrics tend to exhibit undesirable parasitic capacitance, crosstalk noise, dynamic power dissipation, and interconnect propagation delay. Accordingly, polymeric dielectrics have gained widespread attention. In particular, perfluorinated polymers such as polytetrafluoroethylene have been proposed for use as an interlevel dielectric material. See, e.g., Singh et al., “Semiconductor Manufacturing in the 21^{st} Century,” Semiconductor Fabtech, 29^{th} ed., March, 1999, pp. 223-232. However, such polymeric coatings are generally applied through solvent-based techniques which are unsuited for microelectronic devices requiring precise microstructural control. In addition, while chemical vapor deposition techniques are known for certain dielectric applications, such techniques are generally unknown for perfluorinated polymers such as polytetrafluoroethylene in the context of microelectronic device manufacturing.

Thus, there exist opportunities in the art to provide alternatives and improvements to known halogenated polymeric coating technologies for semiconductor application. In particular, it has been discover that halogenated polymeric coatings, e.g., fluorinated and/or chlorinated polymeric coatings, may be used as an interlevel dielectric material and/or to increase the strength of semiconductor members.

### SUMMARY OF THE INVENTION

One aspect of the invention provides a coated semiconductor member. The member includes front and rear surface and an optional semiconductor microelectronic device that is accessible from the front surface. A carbon-containing halogenated polymeric coating is bonded to at least one of the surfaces. The semiconductor member may be comprised of a single crystalline material consisting essentially of a single element, e.g., Si or Ge. However, compound semiconductors, e.g., III-V semiconductors such as GaAs, may be used as well. In any case, the semiconductor member may take any of a number of forms, including, but not limited to, the form of a chip or a wafer. However, when the member is not intended for microfluidic applications, the member may contain no fluid-transporting feature.

Typically, the coating is non-reworkable. In addition, coating may be bonded to the surface in a manner and quantity effective to provide the member an increased strength. For example, the coating may be bonded to the rear surface. Such a coating may have a thickness of about 1 μm to about 50 μm that serves to increase the strength of the member by at least about 4%. For example, a member-strengthening coating may contain a —SiO moiety. The —SiO moiety may be provided as a component of silica or a polymer, e.g., as a portion of a polymeric backbone or a group pending from a polymeric backbone. In addition or in the alternative, the coating may contain a cyclic moiety such as a benzyl moiety. In any case, the coating is typically fluorinated, chlorinated, or both. For example, the coating is formed from polymerization of a fluid containing chlorobenzotrifluoride.

The coating may be bonded to the front surface, regardless whether the rear surface has a coating bonded thereto. Optionally, the coating may serve as an interlevel dielectric material in a semiconductor microelectronic device. For example, the coating may be used as a component of a transistor by its placement between electrically conductive features, metallic or otherwise, on the front surface. Coatings with a dielectric constant of no more than about 2.5 are particularly suited for such an application. Similarly, a loss tangent of no more than about 0.001 is also preferred.

Entirely polymeric coatings may be used as an interlevel dielectric material. For example, fluorinated polymers, and more specifically, perfluorinated polymers such as polytetrafluoroethylene and polyhexafluoropropylene exhibit excellent materials properties to serve as an interlevel dielectric material. Such polymers coatings may be applied in a context that does not involve a photoresist. In some instances, any fluorinated but not chlorinated polymer, if present in the coating, has a microstructure resulting from vapor phase in situ addition polymerization.

The invention also provides a method for coating a semiconductor member. The method involves dispensing a fluid onto one or more surfaces of a member as described above. The fluid is subjected to conditions effective to produce a carbon-containing halogenated polymeric coating bonded to the one or more surfaces onto which the fluid is dispensed. In particular, the fluid may be gaseous. In addition, a least some of the fluid may be subject to in situ addition polymerization to form the polymeric coating. Furthermore, the coating formed may provide the member an increased strength.

### BRIEF DESCRIPTION OF THE DRAWINGS

FIG. 1 schematically depicts in cross-sectional view an exemplary semiconductor microelectronic device that includes an interlevel dielectric coating.

FIG. 2 is a micrograph showing in cross-sectional view a semiconductor wafer having a polyceramic coating on a polished surface thereof.

FIGS. 3A and 3B, collectively referred to as FIG. 3, are micrographs of coated and diced semiconductor wafers.

FIG. 4 is a graph that shows the results of impact testing of semiconductor microelectronic devices with and without polyceramic coatings.

FIG. 5 is a graph that shows that results of 3-point bend testing of semiconductor microelectronic devices with and without polyceramic coatings.

### DETAILED DESCRIPTION OF THE INVENTION

Before describing the present invention in detail, it is to be understood that the invention is not limited to specific microelectronic devices or types of electronic products, as such may vary. It is also to be understood that the terminology used herein is for the purpose of describing particular embodiments only, and is not intended to be limiting.

As used in this specification and the appended claims, the singular article forms “a,” “an,” and “the” include both singular and plural referents unless the context clearly dictates otherwise. Thus, for example, reference to “a coating” includes a plurality of coatings as well as a single coating, reference to “a surface” includes one or more surfaces, reference to “a chip” includes a single chip as well as a collection of chips, and the like.

In general, the invention pertains to the use of a coating to improve electronic and/or mechanical properties associated with a semiconductor member. The semiconductor member may take any of a number of forms, including, but not limited to, the form of a chip, or a wafer. Typically, the member has opposing front and rear major surfaces. However, semiconductor members of any geometry may benefit from the invention. In addition, the invention may be used in conjunction with semiconductor members used for any of a number of applications, including, for example, microelectronic devices, micro-electromechanical systems (MEMS), optical devices, and microfluidic devices. Accordingly, the semiconductor member may contain or exclude specific feature according to the intended use of the member. That is, the construction and structural features of the member are selected according to the intended use of the member. For example, when the member is not intended for microfluidic applications, the member may contain no fluid-transporting feature.

When the semiconductor member includes a microelectronic device, the device is typically accessible from the front surface of the device, and the invention may be used to improve the device's electronic properties. In some instances, the semiconductor member is or consists essentially of the microelectronic device. However, the invention may be used to improve the mechanical properties of any semiconductor member, regardless whether the member is used in a microelectronic context. For example, the semiconductor member may be comprised of a single crystalline material consisting essentially of a single element, e.g., Si or Ge, or a compound semiconductor, e.g., a III-V semiconductor such as GaAs. The presence or absence of dopants is not critical to the invention. Alternatively, the semiconductor member may be comprised of a multicrystalline or amorphous semiconductor material such those that may be found in photovoltaic applications. The invention may be advantageously employed in conjunction with technologies that employ either direct and indirect band gap semiconductors.

The coating is partially or fully polymeric and contains carbon. The terms “polymer,” “polymeric,” and the like are used in their ordinary sense and refer to any of numerous natural and synthetic compounds formed from a plurality of monomeric units. Polymer such as dimers, trimers, and oligomers as well as compounds having extremely high molecular weights such as those formed from one-hundred or more monomeric units. In addition, the term polymer include, for example, homopolymers as well copolymers, linear as well as branch polymers, crosslinked as well as uncrosslinked polymers.

While SiOₓ is sometimes considered polymeric in nature, a coated semiconductor member consisting of only a semiconductor member and a pure SiOₓ coating on a surface thereof is excluded from the invention. Nevertheless, the coating may contain a —SiO moiety. For example, the —SiO moiety may be provided in silica particles in the coating. In addition, the —SiO moiety may be provided as a constituent of a polymer. Silicones such and polysiloxanes are well known polymers containing —SiO moieties in their backbone. Polymers having —SiO moieties pending from its backbone may be advantageously used as well.

In addition, the coating contains a halogen. The term “halogen” is used in the conventional sense and refers, for example, to a fluoro, fluoride, chloro, chloride, bromo, bromide, iodo or iodide moiety. The halogen is typically a part of the polymeric portion of the coating, if the coating is not entirely polymeric. Thus, for example, when the polymeric portion of the coating contains an alkyl group such as a branched or unbranched saturated hydrocarbon group containing 1 to about 24 carbon atoms, such as methyl, ethyl, n-propyl, isopropyl, n-butyl, isobutyl, t-butyl, octyl, 2-ethylhexyl, decyl, and the like, the alkyl group may be halogenated. That is, such a coating may contain a halogenated alkyl group. Similarly, the polymeric portion of the coating may contain an alkenyl or alkynyl group, wherein at least one of the hydrogen atoms in the group is optionally replaced with a halogen atom. Furthermore, the polymeric portion of the coating may contain an alkoxy group, i.e., an alkyl group bound through a single, terminal ether linkage.

In general, the chemical structure of the coating may include or exclude any group or moiety according to the intended function of the coating. In some instances, the coating may contain cyclic and/or aromatic groups. For example, the coating may contain an aryl group having a univalent aromatic substituent containing a single aromatic ring or multiple aromatic rings that are fused together or linked covalently. Similarly the coating may contain an arylene group having a divalent aromatic substituent containing a single aromatic ring or multiple aromatic rings that are fused together or linked covalently. Exemplary aryl and arylene groups may contain an aromatic ring or a plurality of fused or linked aromatic rings. However, heterocyclic moieties may be included as an alternative or additional constituent. Aryl and arylene groups contain one or more substituent groups or have at least one carbon atom is replaced with a heteroatom. Exemplary polymers containing cyclic moieties include polycarbonate, polyimide, polyethylene terephthalate, and polystyrene. In particular, polymer families such as polyarylene ethers, polyarylenes, parylenes, polyimides, aromatic hydrocarbons, benzocyclobutenes are known in the semiconductor microelectronic industry.

In any case, the coating is typically fluorinated, chlorinated, or both. For example, the above-mentioned polymers and polymer families may be fluorinated or chlorinated by methods known in the art. Exemplary commercially available fluorinated and/or chlorinated polymers include polyvinylchloride, polyvinylfluoride, polyvinylidene fluoride, polyvinylidene chloride, polychorotrifluoroethylene, polytetrafluoroethylene, polyhexafluoropropylene, and copolymers thereof.

As alluded to above, nonpolymeric fillers particles may be included as a component of the polymeric coating. For example, semiconductor, metallic and/or ceramic filler particles may be used to enhance the mechanical, electrical, or optical properties of the fillers. When the filler particles are ceramic, the film may comprise a polyceramic material. The particles may be crystalline or amorphous in nature. Exemplary ceramic particles suitable for use with the invention include, oxides such as silica, alumina, zirconia, and titania, nitrides such as silicon nitride, and titanium nitride, and metal halides. Depending on the intended application, single metal or mixed metal ceramics may be used.

The polymeric coating may be bonded to any surface of the semiconductor microelectronic device. However, when the semiconductor has one or more major surfaces, the coating is typically bonded a major surface. For example, when the semiconductor member has front and rear surfaces, the coating is bonded at the front surface, the rear surface, or both surfaces. In addition or in the alternative, the coating may be bonded to one or more side surfaces that may or may not be a major surface. In any case, depending on the intended application, an entire surface or merely a portion thereof may have a polymeric coating bonded thereto. Optionally, more than one type of polymeric coating may be employed in conjunction with the invention.

Typically, the polymeric coating is non-reworkable. In addition, the coating is generally not used as a photoresist. However, photoresist technologies may be used in to pattern the coating, as discussed below.

The polymeric coating is generally formed by dispensing a fluid onto one or more surfaces of a semiconductor member. As used herein, the term “fluid” as used herein refers to matter that is not completely solid and is at least partially gaseous and/or liquid. A fluid may contain a solid that is minimally, partially, or fully solvated, dispersed, or suspended. Examples of fluids include gases such as mixtures of an inert gas and a reactive polymerizable gas, aqueous liquids such as water-based emulsions, and nonaqueous liquids such as organic solvents having polymers dissolved therein, or suspensions such as a composition containing solid particulates suspended in a liquid. Once the fluid is dispensed, the fluid is subjected to conditions effective to produce a carbon-containing halogenated polymeric coating bonded to the one or more surfaces onto which the fluid is dispensed. Optionally, the surface or surfaces of the semiconductor member onto which the fluid the fluid is dispensed may be pretreated to promote adhesion of the polymeric coating thereon.

Depending on factors such as the fluid dispensed, the dispensing technique and the conditions to which the dispensed fluid is subjected, the microstructure of the polymeric coating formed may differ. For example, the polymeric coating may be formed by dispensing a liquid coating material via casting, spin coating, spray coating, printing or other techniques. In addition, vapor phase fluid deposition techniques may be used as well. Often, vapor phase deposition involves vacuum deposition techniques used in semiconductor fabrication. Such vacuum processes include, but are not limited to, physical vapor deposition, chemical vapor deposition, and evaporation. Due to the greater mobility gases relative to liquids, however, coatings produced through vapor phase deposition tend to exhibit a microstructure that conforms more closely to the surface on which they are formed than coatings formed by solvent casting. For example, coatings containing fluorinated but not chlorinated polymers exhibit a microstructure of exceptional conformity to surface onto which they are coating through vapor phase in situ addition polymerization. The morphology associated with the microstructure of vapor phase deposited coatings is distinct from the morphology associated with coatings formed through other deposition means.

In some instances, the polymeric coating may be formed through in situ polymerization or crosslinking. For example, a fluid containing monomers may be dispensed onto a member surface for polymerization. The polymerization may be effected, e.g., through thermal, chemical, or photolytic curing. Thermally curable polymers tend to require heating of the fluid. Chemically curable polymers tend to require an appropriate curing agent. Exemplary polymerization mechanisms include step polymerization and addition polymerization. Optionally, a polymer formed from such techniques may be terminated with a moiety different from the remaining portion thereof. For example, modified phenoxy binders may be used in conjunction with the invention.

In the alternative, already formed polymers may be deposited directly onto the surface to form the polymeric coating. For example, thermoplastic polymers, i.e., polymers having a relatively large window of thermostability, may be deposited using processes that involve involving extrusion and/or injection. In addition, solvents may be used to dissolve polymers for dispensing. Once dispensed, the solvent may be evaporated through the application of heat and/or vacuum. One of ordinary skill in the art will recognize that the solubility of a particular polymer in a particular solvent will depend in large part by the polarity of polymer and the solvent. Polymers tend to exhibit a high solubility in solvents of like polarity and a low solubility in solvents of dissimilar polarity. Thus, for example, chlorobenzotrifluoride, is a particularly desirable solvent for polymers and/or monomers containing a benzyl and/or a halogen moiety.

As alluded to above, the invention provides an improved semiconductor microelectronic device. In particular, the coating of the invention provides a number of material properties that may be exploited to overcome performance barriers associated with integrated circuits (IC). Digital circuits on ICs have reached speed limits due to propagation delays (e.g., interconnect delays and gate delays). The problems with such delays are well documented. Signal propagation delays for such circuits may be reduced by lowering the RC (resistance-capacitance) time constant of such circuits.

There are two ways to reduce the RC time constant of a circuit. The first is to increase the electrical conductivity of the conductors in the circuit. The second is to reduce the dielectric constant of insulators in the circuit. For example, by using copper in place of aluminum in a circuit, electrical resistance of the circuit may be reduced significantly, e.g., by a factor of about 2. In addition, by replacing silicon dioxide having a dielectric constant of approximately 3.6 with polytetrafluoroethylene having a dielectric constant of approximately 2, signal propagation delay may be reduced as well.

Thus, the invention provides a coated semiconductor member comprising a microelectronic device. The coating may be used to as an insulator in metal-on-semiconductor (MOS) applications, e.g., as an interlevel dielectric material, and/or as a component of a transistor. For example, the coating may be located between electrically conductive features, e.g., metallic features on the front surface. In addition, the coating has a dielectric constant (K) of no more than about 2.5 and/or a loss tangent of no more than about 0.001. For example, perfluorinated polymers such as polytetrafluoroethylene has a loss tangent of approximately 0.0003, and, when provided as a thin film, tend to be substantially transparent to microwaves.

In particular, entirely polymeric coatings may be formed via in situ vapor phase addition polymerization having a microstructure that is well suited for electronic applications. Unlike processes which involve placing polymeric powder on a surface and melting the powder to form a coating on the surface, in situ vapor phase addition polymerization techniques provide excellent control over the thickness of polymer coatings deposited on a surface. In addition, as discussed above, coatings formed via in situ vapor phase addition polymerization techniques exhibit exceptional conformation and adhesion to the surface onto which they are deposited. Such polymerization techniques may involve step growth mechanisms. While such coatings have been used in a number of different contexts, e.g., to waterproofing textiles or to cover implantable probes for neurosurgery, (see technology review), they are unknown in the context of interlevel dielectric and other semiconductor device applications. In particular, in situ vapor phase addition polymerization to form partially fluorinated and/or perfluorinated polyalkylene coatings are generally unknown in the context of microelectronic semiconductor devices.

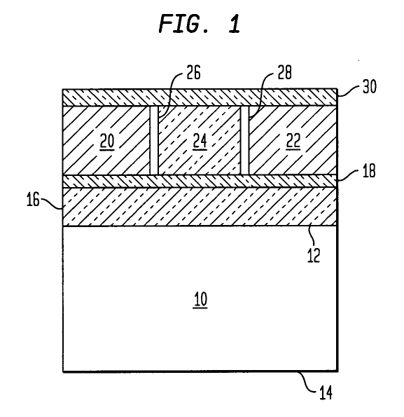

FIG. 1 depicts in cross-sectional view the first level of an exemplary semiconductor device that includes an interlevel dielectric coating. The coating may be used in multilevel interconnect structures. As with all figures referenced herein, in which like parts are referenced by like numerals, FIG. 1 is not to scale and certain dimensions may be exaggerated for clarity of presentation. As shown, a semiconductor member 10 is provided having an upper surface 12 and a lower surface 14. Typically, a layer of thermal oxide layer 16 is formed on the upper surface 12. An etchstop layer 18 is provided over the thermal oxide layer. A plurality of electrically conductive features 20, 22 is provided on the etchstop layer 18. Interposed between conductive features 20, 22 and provided on the etchstop layer 18 is a low-K dielectric coating 24. Interposed between the dielectric coating 24 and each of electrically conductive features 20, 22 are diffusion barriers 26, 28. An additional etchstop layer 30 is deposited the electrically conductive features 20, 22, the diffusion barriers 26, 28 and the dielectric coating 24.

In general, the device of FIG. 1 may be made from a variety of materials. Typically, the semiconductor member 10 is comprised of Si, and the thermal oxide layer 16 is comprised of silicon oxide. The etch stop layers 18, 20 may include nitrides such as Si₃N₄. In addition, the diffusion layers may include Ta or TaN. Any conductive material may be used to form the electrically conductive features 20, 22. However, due to its relatively high conductivity relative to its cost, Cu is typically used to form the electrically conductive features 20, 22. Similarly, while the dielectric coating may take the form of SiO₂ which has a dielectric constant of about 3.7, the invention may instead employ a halogenated polymeric coating having a lower dielectric constant, e.g., polytetrafluoroethylene having a dielectric constant of about 2.1.

As discussed above, the halogenated polymeric coating may be deposited through in situ addition polymerization. For example, perfluorinated monomeric gases may be reacted to form perfluorinated polymeric coatings on a surface of a semiconductor member. For example, tetrafluoroethylene or a perfluorinated ring or 3 or more carbons may be used as monomers for forming perfluorinated polymeric coatings. Selective deposition may be effected through the use of photoresist masking. Examples of such gaseous monomers include simple molecules such as tetrafluoroethylene, cyclic molecules such as perfluorocyclobutane, oxygen-containing molecules such as perfluoroacetone, hexafluoropropylene oxide, and mixtures thereof. Often, polymerization takes place via addition reaction mechanism. In addition, radical density associated with addition polymerization may determine whether an amorphous films, crystalline ribbons, and/or spherulites are formed.

It has further been discovered that certain conformal polyceramic coatings previously unknown in the context of semiconductor technologies may be used to increase the strength of a semiconductor member, particularly in the context of wafer dicing. Polyceramic coating such as those marketed by NIC Industries (White City, Oreg.) under the trademark Cerakote™ have previously been used in the contexts of clear protection, performance motor sports, industrial coating applications, firearms coatings, gas turbine engine coatings, and decorative performance coatings. For example, polyceramic coatings have been applied on the surfaces of public structures and buildings to repel paints and other substances used for applying graffiti. Typically, such coatings exhibit high chemical and corrosion resistance, e.g., resistant to attack by solvents acids, and bases, exceptional hardness, and outstanding UV resistance. In addition, such coatings can be removed by laser ablation without vaporizing in a manner such that the vapors condense back onto the laser.

A number of experiments have been performed, the results of which support this discovery. The experiments focused on the polyceramic formulation from NIC Industries designed MC-182. This formulation is provided as a proprietary mixture of chlorobenzotrifluorides, solids, and reactive compounds for forming a silica-based polyceramic coating. However, it is expected that other polyceramic formulations will yield similar results. For example, the formulations described in U.S. Pat. Nos. 5,853,894, 6,156,389, 6,447,979, 6,495,624, 6,663,941, and 6,767,587, particularly those involving perfluorinated mono-functional or multifunctional silanes, may be suited for use with the invention.

In general, MC-182 tends to produces a covalent bond with the surface to which it is applied. MC-182 coatings exhibits superior protective properties in that if the coatings are scratched to exposed the underlying surface, only the exposed part of the surface may be attacked by corrosive agents. The corrosive agent may not attack and propagate through interface between the coating and the underlying surface. This property is very desirable for opening very fine pitch vias on semiconductor devices.

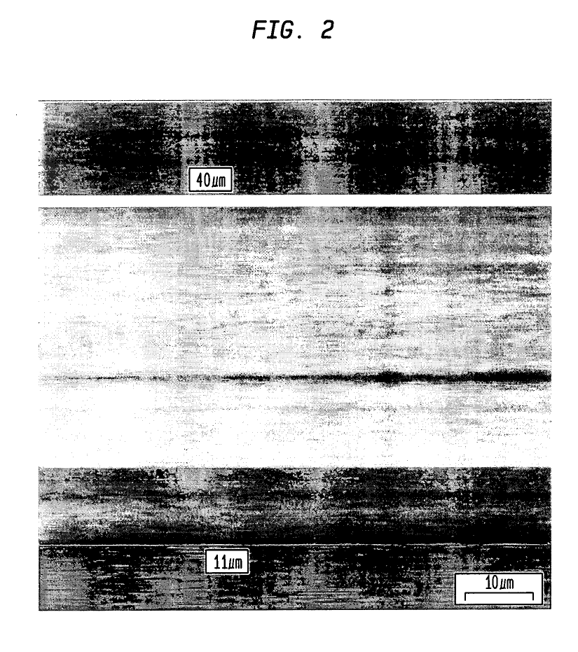

FIG. 2 is a micrograph showing in cross-sectional view a semiconductor wafer having a polyceramic coating on a polished surface thereof. As shown, a silicon wafer having a thickness of about 75 μm was provided having a polished major surface and an opposing major surface. An MC-182 coating of approximately 11 μm was formed on the polished surface, and the opposing surface was ground such that the wafer thickness was reduced to about 40 μm.

A nanoindenter probe capable of continuously monitoring the elastic modulus and hardness within a depth from the coating to a 2 μm depth was used to take a total of four measurements on a MC-182 coated wafer. Consistent results were obtained. The results indicated that the elastic moduli and hardness increased with depth. The elastic modulus changed from about 5 GPa near the surface to about 60 GPa at 2 μm below the surface. The hardness changed from about 0.5 GPa near the surface to about 1.4 GPa at 2 μm below the surface. The polyceramic coatings elastic modulus at depth approached that of a fused silica standard (about 75 GPa). However, the hardness of the coating at depth was substantially lower than fused silica standard (about 10 GPa). In short, MC-182 produced a semi-hard yet strong coating.

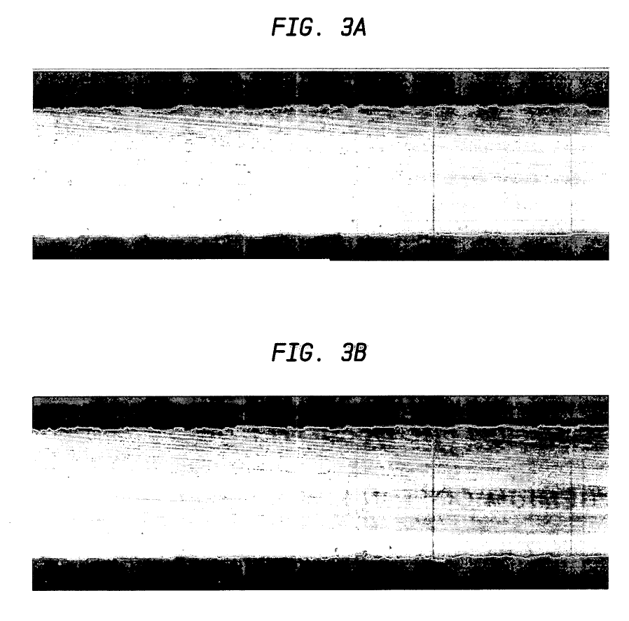

FIG. 3 shows in cross-sectional view semiconductor wafers similar to that depicted in FIG. 2, except that the wafer was diced with the coating surface facing downward and the polished surface facing upward. As shown, dicing serrations were present but, no wafer chipping was observed in these micrographs. Accordingly, these micrographs demonstrate that MC-182 is an excellent supportive material for dicing wafers. When the MC-182 coating was applied on the rear surface of the face of a wafer, the coating exhibited sufficient hardness and strength to allow wafer dicing, but was soft enough to absorb and/or cancel the unavoidable saw blade vibrations associated with the dicing process.

In circumstances where the MC-182 coating was chipped, it was observed that the chips will not propagate through the semiconductor wafers. Absent microcracks in the diced wafers, the wafers are less likely to crack under thermal and/or stress loads. In addition, the absence of microcracks allows dicing operations to be performed under suboptimal conditions, such as those associated with incorrect spindle speed, incorrect travel speed, incorrect dicing blade grit, incorrect dicing blade widths, etc.

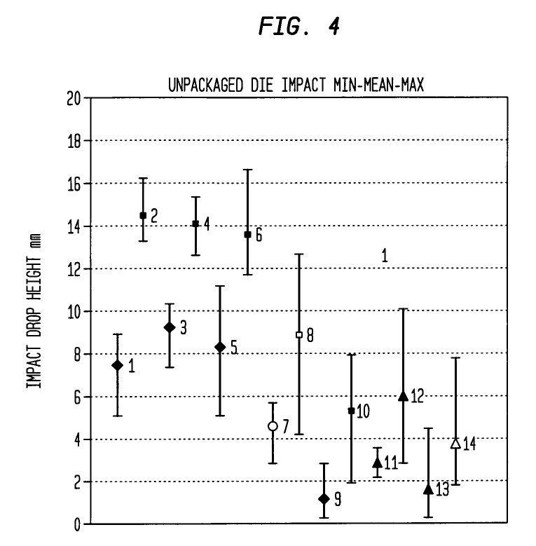

Impact testing was performed on various unpackaged semiconductor microelectronic devices without a coating relative to the same devices having a coating of MC-182. The devices were obtained from Grinding and Dicing Services, Inc (GDSI), and Silicon Quest International, Inc. (SQST). A 150 g rounded steel impactor was used. In addition the height of the impactor was increased by approximately 0.13 mm between impacts. The parameters of impact testing are listed in Table I. They include: a reference number of each test, the source of the devices for each test, device thickness of each test, the condition of the rear device surfaces, the position of the device circuits relative to the impactor, and the surface on which the coating is located. The results of impact testing of dies with and without polyceramic coatings are shown in FIG. 4, wherein the average, high, and lows of the impact drop height to failure are plotted for each test. The impact drop height for the tests corresponds to the strength of the devices tested.

TABLE 1

| Reference | | Device | | Surface | Circuit | Coating |
|---|---|---|---|---|---|---|
| Number | Source | Thickness | | Condition | Position | Position |
| 1 | GDSI | 150 | μm | Polished | Up | None |
| 2 | GDSI | 150 | μm | Polished | Down | None |
| 3 | GDSI | 150 | μm | Ground | Up | None |
| 4 | GDSI | 150 | μm | Ground | Down | None |
| 5 | GDSI | 150 | μm | Ground | Up | Down |
| 6 | GDSI | 150 | μm | Ground | Down | Up |
| 7 | SQST | 150 | μm | Ground | Up | None |
| 8 | SQST | 150 | μm | Ground | Down | None |
| 9 | SQST | 75 | μm | Ground | Up | None |
| 10 | SQST | 75 | μm | Ground | Down | None |
| 11 | SQST | 75 | μm | Ground | Up | Down |
| 12 | SQST | 75 | μm | Ground | Down | Down |
| 13 | SQST | 75 | μm | Ground | Up | Up |
| 14 | SQST | 75 | μm | Ground | Down | Up |

Notably, impact testing shows that device coated with MC-182 exhibit a higher resistance to impact stresses. In general, the coating increased the strength of 75 μm device to roughly that of an uncoated 150 μm device. For example, the minimum strength for a coated 75 μm device was comparable to the strength of an uncoated 150 μm device from SQST. In addition, the maximum strength for a coated 75 μm device was comparable to the minimum strength of a 150 μm device from GDSI. The variations in impact drop height for each test may be attributed to the variation in coating thickness.

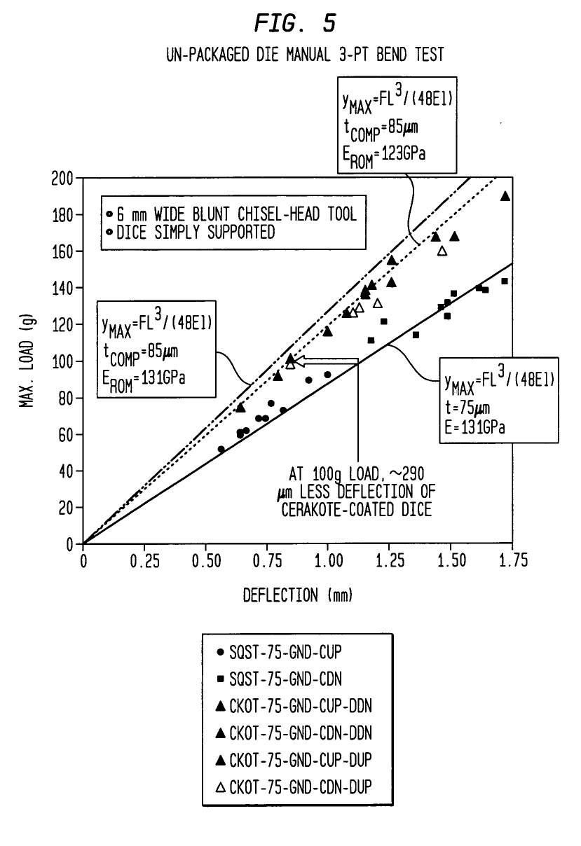

In addition, three-point bend testing was performed on the devices corresponding to reference numbers 9-14 in Table 1. The results of such testing are shown in FIG. 5, in which the maximum load for each test is plotted against deflection. The results show in general that the coated devices are both stronger and stiffer. For example, an uncoated silicon device bends approximately 290 μm more than the same device under the same loading of 100 g.

By extrapolation, it can be observed that a 75 μm device having a MC-182 coating of 10 μm is approximately 92 percent as strong as a theoretical 85 μm device without a coating. This indicates that such a coating increases the strength of the device by approximately 9%. Alternatively stated, a 75 μm device may be thinned by 10 μm, have 10 μm coating of MC-182 applied in place of the material removed, and the device would lose only about 8% of its strength. However, impact resistance and chemical resistance will be enhanced in either case.

Thus, the experimental results discussed above show that the invention provides a halogenated polymeric coating bonded to a surface of the semiconductor member in a manner and quantity effective to provide the member an increased strength. For example, the coating may provide the member an increase at least about 4% over the precoat strength. In some instances, the member's strength is increased by at least about 8%. The increased strength is particularly useful to prevent or mitigate semiconductor member cracking or breaking when semiconductor wafers are diced to form chips.

Typically, covalent bonding is established between the coating and the semiconductor member. Covalent bonding tends ensure that the interface between the coating and the member is susceptible to attack or to debonding. Debondable coatings, as a whole, do not generally strength the member to a significant degree. However, acceptable bonding performance between the coating and the semiconductor member may be achieved through ionic or van der Waal forces as well.

The coating may have a thickness of about 1 μm to about 50 μm. For example, a typical coating may have a thickness of about 5 μm to about 20 μm. Optimally, the thickness of the coating is substantially uniform, e.g., does not deviate from the mean by more than about 10%. The coating thickness may be determined by the composition of the precursor fluid, e.g., the proportion of solvent to solvate, and/or by the technique by which the fluid is applied.

Percursor fluids for conformal polyceramic coatings may be applied to semiconductor members using any of a number of techniques. For example, such fluids may be applied by wiping, brushing, spraying, and dipping. In some instances, a single application is sufficient to produce a strength enhancing coating. When the semiconductor member is provided in the form of a wafer, the precursor fluid may be applied through spin coating any other techniques known in the art of semiconductor fabrication. In addition, the coating may serve a planarizing function.

Variations of the present invention will be apparent to those of ordinary skill in the art. For example, different isomers of chlorobenzotrifluoride, e.g., ortho, para, meta, may be used as a solvent/suspension medium for a polyceramic precursor fluid. Other aromatic, chlorinated and/or fluorinated solvents/suspension media may be used as well. Additional variations of the invention may be discovered upon routine experimentation without departing from the spirit of the present invention.

Although the invention herein has been described with reference to particular embodiments, it is to be understood that these embodiments are merely illustrative of the principles and applications of the present invention. It is, therefore, to be understood that numerous modifications may be made to the illustrative embodiments and that other arrangements may be devised without departing from the spirit and scope of the present invention as defined by the appended claims.

All patents, patent applications, and publications mentioned herein are hereby incorporated by reference in their entireties.

1. A coated semiconductor member, comprising:
a member containing no fluid-transporting feature, having front and rear surfaces, and comprising a semiconductor microelectronic device that is electrically accessible from the front surface; and
a non-reworkable carbon-containing halogenated polymeric coating bonded to at least one of the surfaces, wherein any fluorinated but not chlorinated polymer, if present in the coating, has a microstructure associated with vapor phase in situ addition polymerization.

2. The semiconductor member of claim 1, in the form of a chip.

3. The semiconductor member of claim 1, in the form of a wafer.

4. The semiconductor member of claim 1, wherein the coating is bonded to the rear surface.

5. The semiconductor member of claim 4, wherein the coating contains a —SiO moiety.

6. The semiconductor member of claim 5, wherein the coating contains silica.

7. The semiconductor member of claim 5, wherein the —SiO moiety represents a portion of a polymeric backbone.

8. The semiconductor member of claim 5, wherein the —SiO moiety is pendant from a polymeric backbone.

9. The semiconductor member of claim 4, wherein the coating contains a cyclic moiety.

10. The semiconductor member of claim 9, wherein the cyclic moiety is a benzyl moiety.

11. The semiconductor member of claim 1, wherein the coating is fluorinated, chlorinated, or both.

12. The semiconductor member of claim 11, wherein the coating contains a fluorinated and chlorinated polymer.

13. The semiconductor member of claim 12, wherein the coating is formed from polymerization of a fluid containing chlorobenzotrifluoride.

14. The semiconductor member of claim 1, in the absence of photoresist.

15. The semiconductor member of claim 1, wherein the coating is bonded to the front surface.

16. The semiconductor member of claim 15, wherein the coating is located between electrically conductive features on the front surface.

17. The semiconductor member of claim 16, wherein the electrically conductive features are metallic.

18. The semiconductor member of claim 15, wherein the coating represents a component of a transistor.

19. The semiconductor member of claim 15, wherein the coating has a dielectric constant of no more than about 2.5.

20. The semiconductor member of claim 15, wherein the coating has a loss tangent of no more than about 0.001.

21. The semiconductor member of claim 15, wherein the coating is fluorinated.

22. The semiconductor member of claim 21, wherein the coating is perfluorinated.

23. The semiconductor member of claim 21, wherein the coating is entirely polymeric.

24. A coated semiconductor member exhibiting an increased strength, comprising:
a member comprising a semiconductor and having a surface, wherein the member is associated with a precoat strength; and
a carbon-containing halogenated polymeric coating bonded to the surface in a manner and quantity effective to provide the member an increased strength that is at least 4% higher than the precoat strength.

25. The semiconductor member of claim 24, comprising a single crystalline material consisting essentially of a single element.

26. The semiconductor member of claim 25, wherein the element is selected from the group consisting of Si and Ge.

27. The semiconductor member of claim 24, comprising a single crystalline material consisting essentially of a compound semiconductor.

28. The semiconductor member of claim 27, wherein the compound semiconductor is a III-V semiconductor.

29. The semiconductor member of claim 24, having opposing major surfaces, wherein the coating is bonded to at least one of the major surfaces.

30. A coated semiconductor member exhibiting an increased strength, comprising:
a member comprising a single crystalline semiconductor and having a surface, wherein the member is associated with a precoat strength; and
a carbon-containing polymeric coating bonded covalently to the surface in a quantity effective to provide the member an increased strength that is at least 4% higher than the precoat strength.

31. A coated semiconductor member exhibiting an increased strength, comprising:
a member comprising a semiconductor and having a surface, wherein the member is associated with a precoat strength; and
a carbon-containing halogenated polymeric coating having a thickness of about 1 μm to about 50 μm bonded to the surface in a manner effective to provide the member an increased strength that is at least 4% higher than the precoat strength.

32. A coated semiconductor member, comprising:
a member comprising a semiconductor and having a surface; and
a nonreworkable carbon-containing fluorinated and chlorinated polymeric coating bonded to the surface.

33. A coated semiconductor member, comprising:
a member comprising a semiconductor and having a surface; and
a halogenated polymeric coating bonded to the surface, wherein the coating contains a cyclic moiety and a —SiO moiety.

34. A method for coating a semiconductor member, comprising:
(a) dispensing a fluid onto one or more surfaces of a member containing no fluid-transporting feature, having front and rear surfaces, and comprising a semiconductor microelectronic device that is electrically accessible from the front surface; and
(b) subjecting the fluid to conditions effective to produce a nonreworkable carbon-containing halogenated polymeric coating bonded to the one or more surfaces onto which the fluid is dispensed, wherein any fluorinated but not chlorinated polymer, if present in the coating, has a microstructure associated with vapor phase in situ addition polymerization.

35. The method of claim 34, wherein the fluid is gaseous.

36. The method of claim 34, wherein step (b) comprises polymerizing at least some of the fluid dispensed onto the one or more surface to form the polymeric coating.

37. The method of claim 36, wherein step (b) comprises carrying out addition polymerization.

38. A method for coating a semiconductor member, comprising:
(a) dispensing a fluid onto a surface of a member having a surface and comprising a semiconductor; and
(b) subjecting the fluid to conditions effective to produce a carbon-containing halogenated polymeric coating bonded to the surface in a manner and quantity effective to provide the member an increased strength that is at least 4% higher than the precoat strength.
